(19) United States
(12) Patent Application Publication
(10) Pub. No.: US 2008/0236652 A1
(43) Pub. Date: Oct. 2, 2008

(54) METHOD OR MEANS TO USE OR COMBINE PLASMONIC, THERMAL, PHOTOVOLTAIC OR OPTICAL ENGINEERING

(76) Inventors: Anthony Defries, Los Angeles, CA (US); Mark Brongersma, Redwood City, CA (US)

Correspondence Address: MATTER, INC., 1079 CARRARA PLACE, LOS ANGELES, CA, 90049, US

(21) Appl. No.: 11/959,309

(22) Filed: Dec. 18, 2007

Related U.S. Application Data
(60) Provisional application No. 60/870,686, filed on Dec. 19, 2006.

(51) Int. Cl. H01L 31/058

(52) U.S. Cl. 136/248; 977/948

(57) ABSTRACT

Means to use and combine methods of thermal engineering, plasmonics, photonics, electronics, photovoltaics, optical transfer, heat transport, light transport, catalysis and chemical reactions individually or in any combination for the enhancement or generation of solar, optical, electrical or any form of energy. The present disclosure further concerns a means to use at least a form of electromagnetic excitation or light-matter interactions in a structure or material having one or more addressable frequencies to generate the exchange of thermal, kinetic, electronic or photonic energy. The present disclosure further concerns a means to use at least a form of electromagnetic excitation or light-matter interaction, including solar or laser energy to generate localized conditions that enable initiation and spatial and temporal control of catalysis, chemical reactions, deposition, growth, synthesis, photocatalysis, photosynthesis, chemical catalysis, photochemical catalysis, photovoltaic, electrocatalysis and catalytic processes.

### CROSS REFERENCE TO RELATED APPLICATIONS

This application claims benefit of and priority to U.S. Provisional Patent Application No. 60/870,686 filed Dec. 19, 2006 entitled “A Means to Use or Combine Thermal Engineering, Optical, Plasmonic or Photovoltaic Methods for Energy or Power Generation”.

### BACKGROUND

1. Field

The present disclosure concerns a means to use and combine methods of thermal engineering, plasmonics, photonics, electronics, photovoltaics, optical transfer, heat transport, light transport, catalysis and chemical reactions individually or in any combination for the enhancement or generation of solar, optical, electrical or any form of energy or for any other purpose. The present disclosure further concerns a means to use at least a form of electromagnetic excitation or light-matter interactions in a structure or material having one or more addressable frequencies to generate the exchange of thermal, kinetic, electronic or photonic energy. The present disclosure further concerns a means to use at least a form of electromagnetic excitation or light-matter interaction, including solar or laser energy to generate localized conditions that enable initiation and spatial and temporal control of catalysis, chemical reactions, deposition, growth, synthesis, photocatalysis, photosynthesis, electrocatalysis and catalytic processes. Initiation and spatial and temporal control may be obtained by restricting and directing the electromagnetic excitation or light-matter interactions to specific objects or features embedded or located in or on a host matrix material or substrate. In some implementations this may provide a means to use electromagnetic excitation or light-matter interactions to influence, cause, control, modulate, stimulate or change the state or phase of electrical, magnetic, optical, thermal, acoustic or electromagnetic charge, emission, conduction, recording, data management, storage or similar properties. The method could include the use of light-matter interactions to generate electromagnetic excitation and concentrate extremely localized field effects or concentrated plasmonic field effects to cause an exchange of energy states in a material or structure. Said field effects could be used for excitation of surface electrons in metallic nanostructures or any other structures causing said electrons to exchange energy states or said field effects could be used to mediate or stimulate photon emissions or modulate photonic energy to excite or stimulate emissions of electrons. Said electron or photon emissions could be used to drive photochemical, photocatalysis or photovoltaic reactions. Said exchange of energy states could be made to perform the functions of a solar cell, capacitor, battery, transistor, resistor, semiconductor, data, information, or signal storage, recording, acquisition, distribution, management, transport, retrieval, exchange, inversion or restoration. Spatial and temporal control may be obtained by restricting and directing the electromagnetic excitation or light-matter interactions to specific objects or features embedded or located in or on a host matrix material or substrate. The method of use could include control of light-matter interactions addressed at optical and other frequencies to generate controlled localized thermal conditions. A further implementation concerns a means to employ electromagnetic excitation or light-matter interactions to generate localized thermal conditions to control or cause the combination, separation, reformation or reclamation of a gas, a combination of gasses, a material or a combination of materials in the form of a gas, plasma, solid or liquid. The method of use disclosed could provide a means to control chemical reactions for the generation, use, transfer and output of controlled localized thermal heat or energy. The method of use disclosed could provide a means to realize and control local thermal conditions down to or below the length scale of a single nanometer and down to or below the timescale of a single picosecond. In some implementations surface plasmon excitations may be used to realize and control local thermal conditions down to or below the length scale of a single nanometer and down to or below the timescale of a single picosecond.

2. Related Art

Solar energy technology for renewable energy production may supply worldwide energy needs. Assuming that 10%-efficient solar cells are used, the area required to supply world energy demand is estimated to be 750×750 square kilometers or approximately 3% of global desert area. The widespread use of photovoltaic (PV) or thermal solar materials for the production of renewable energy is currently limited by high cost and low efficiency. To make solar the preferred renewable technology requires the means to manufacture efficient and durable solar materials at low cost. The technology must also provide for materials that are recyclable with low environmental impact and can be deployed safely over large surface areas in close proximity to those locations where energy is required, e.g. industrial facilities, cities, towns, residential areas, communities, etc.

Commercially available silicon based semiconductor dielectric materials have a power conversion efficiency rate of approximately 10%. Because of their complex structure and precise engineering requirements, the wafers from which these photovoltaic solar cells are made are expensive to produce and consume significant energy in the fabrication process offsetting any economic or environmental benefits. The 50% failure rate in fabrication adds to the ecological disadvantages. Silicon materials are fragile in operation and deployment with limited lifetimes and diminishing performance.

Solar cells with active regions consisting of organic materials are promising candidates for reducing the cost of energy since they can be manufactured in a roll-to-roll fashion on low-cost plastic substrates. Organic materials lend themselves to novel form factors e.g. composites, flexible thin films, fibers, coatings, tubes or tiles, which may lead to new applications and substantially reduced deployment or installation costs. These materials promise to be more robust than silicon, but need to be deployed over massive areas. Research in the US, Japan and Europe has reported improved power conversion efficiency of organic PV (OPV) materials to 5%. There is no indication that such advanced OPV materials can be manufactured in bulk or made commercially available in any form.

A typical PV solar cell involves the following operation; photon absorption, exciton diffusion, charge transfer, charge separation, and carrier collection. Each step has a loss associated with it, compounding to a large overall loss that limits the practical efficiency of current PV solar cells to less than 10%. Major loss occurs during photon absorption. The complete solar spectrum consists of many different wavelengths. Photon absorption for electron excitation is wavelength dependent. Current PV or thermal solar cells cannot utilize the complete solar spectrum resulting in only a small number of photons that can be used. More than 70% of photons are unused in conventional PV solar cells. Increasing the spectrum utilization or the number of electrons stimulated per photon could increase the overall efficiency of solar materials. Further progress will require the development of materials with smaller energy gaps and reduced energy loss. Photovoltaic cells in which the active layer is a composite of an organic material and semiconducting nanoparticles have shown promise for achieving lower energy gaps. The invention described herein provides a means to capture and utilize the complete solar spectrum and to maximize energy efficiency. It is a feature of the invention described herein to use adjustments in the resonant frequency, size, morphology, distribution and geometry of nanoparticles or nanoparticle materials to stimulate, increase or control the absorption spectrum and exciton diffusion.

No solar cells or materials have been developed or proposed for commercial production that combine the use of photovoltaic and thermal engineering for more efficient conversion. All of the current and proposed photovoltaic and thermal solar cells/materials use toxic, inorganic or ecologically harmful materials and consume substantial fossil fuel or non-renewable energy supplies in fabrication and manufacture. The invention described herein may combine photovoltaic, plasmonic and thermal engineering devices with a variety of non-toxic, organic, recyclable and ecologically stable materials. Said invention provides improved power conversion efficiency and power generation at lower fabrication or energy costs with reduced environmental impact. Said materials or devices could be used for the production of solar, plasmonic, photovoltaic, thermal or other energy.

Plasmon excitations in metallic nanostructures can be exploited to dramatically improve initiation and spatial and temporal control over catalytic chemical reactions and deposition by nanothermal plasmonic engineering. The realization of controlled, nanoscale thermal environments has great fundamental and practical importance. Research in this area is driven by a desire to better control and monitor physicochemical or biochemical reactions and to develop thermally controlled nanoscale devices. In the field of plasmonics the unique optical properties of metallic nanostructures are harnessed to enable routing and manipulation of light at the nanoscale. This control over light-matter interactions is derived from the properties of nanostructured metals that support light-induced surface plasmon excitations or collective electron oscillations.

The method may incorporate metallic nanoparticle catalysts or nanostructures containing metallic nanoparticle catalysts to be included in the said structure or device. The use of light-matter interactions or electromagnetic excitation including solar energy or laser light to control and direct localized thermal conditions down to or below the length scale of a single nanometer and down to or below the timescale of a single picosecond in said catalysts or devices may allow for more precise chemical reactions to be initiated and controlled in those reactors, structures or devices. Rapid changes in the delivery and location of focused heating will reduce cycling times for repeated heating and cooling to improve the efficiency and yield of chemical reactions and processing.

### BRIEF SUMMARY OF THE INVENTION

The present invention concerns a means to use and combine methods of thermal engineering, plasmonics, photonics, electronics, photovoltaics, optical transfer, heat transport, light transport, catalysis and chemical reactions individually or in any combination for the enhancement or generation of solar, optical, electrical or any form of energy. The present invention further concerns a means to use at least a form of electromagnetic excitation or light-matter interactions in a structure or material having one or more addressable frequencies to generate the exchange of thermal, kinetic, electronic or photonic energy. The present invention further concerns a means to use at least a form of electromagnetic excitation or light-matter interaction, including solar or laser energy to generate localized conditions that enable initiation and spatial and temporal control of catalysis, chemical reactions, deposition, growth, synthesis, photocatalysis, electrocatalysis and catalytic processes. Initiation and spatial and temporal control may be obtained by restricting and directing the electromagnetic excitation or light-matter interactions to specific objects or features embedded or located in or on a host matrix material or substrate. In some implementations this provides a means to use electromagnetic excitation or light-matter interactions or light-matter interactions to influence, cause, control, modulate, stimulate or change the state or phase of thermal, electrical, magnetic, optical, acoustic or electromagnetic charge, emission, conduction, recording, data management, information, storage or similar properties. The method could include the use of light-matter interactions to generate electromagnetic excitation and concentrate extremely localized field effects or concentrated plasmonic field effects to cause an exchange of energy states in a material or structure. Said field effects could be used for excitation of surface electrons in metallic nanostructures or any other structures causing said electrons to exchange energy states or said field effects could be used to mediate or stimulate photon emissions or modulate photonic energy to excite or stimulate emissions of electrons. Said electron or photon emissions could be used to drive photochemical, photosynthesis, photocatalysis, photovoltaic or thermophotovoltaic reactions.

### BRIEF DESCRIPTION OF THE DRAWINGS

NOT APPLICABLE

### DETAILED DESCRIPTION OF THE INVENTION

Metals can be thought of as a gas of conduction electrons. Similar to sound waves in a real gas, metals exhibit plasmon phenomena, i.e. electron density waves. Electron density waves can be excited at the interface between a metal and a dielectric. There is also a strong interaction of light with a metallic nanoparticle. At the surface plasmon resonance frequency, the electric field of a light wave induces a collective electron oscillation in the particle. Due to inelastic scattering processes, the kinetic energy of the electrons is rapidly converted to heat and the temperature of the nanoparticle is raised.

The time-varying electric field associated with light waves can exert a force on the gas of negatively charged electrons and drive them into a collective oscillation. There are interesting analogies of this phenomenon to driving a gas of molecules into a resonant collective oscillation by blowing on a flute. The motion of the oscillating electrons in the particles is strongly damped in collisions with other electrons and lattice vibrations (phonons) and the kinetic energy of the electrons is rapidly converted into heat on a 1-10 femtosecond timescale (one femtosecond=one quadrillionth of a second).

This process can be used for the rapid, controlled heating and cooling of particles to enable new methods for micro and nano manufacturing and patterning and molecular synthesis. It is important to note that very low energy input is required to obtain a significant temperature rise in nanoscale particles. This energy can be delivered in a spatially and temporally controlled fashion by solar or light energy, a lamp, a laser or any requisite wavelength light source. When the light source is interrupted the particle cools and the thermal energy gained rapidly dissipates into a larger, cooler thermal mass on which the particle is positioned (10 ps-1ns). This process can be used for very fast switching between low and high temperature states of the particle.

The effects of local heating can be transferred to adjacent particles, materials or structures. Electromagnetic excitation or light-matter interactions of specific objects or features may be used to drive reactions in materials or structures in proximity to the heated object or feature. In the invention described herein, the heat can be used for any purpose including to drive a turbine, engine, stirling engine, generator, converter, photovoltaic converter, alternator, dynamo or any other device to produce an electrical current.

Resonant light-matter interaction effects may be used to attain controlled localized thermal conditions. The invention described herein could provide a means to initiate and control the generation, use, transfer and output of controlled localized thermal energy.

In an exemplary embodiment the invention described herein could provide a method to use thermal engineering for more efficient solar energy. Said use may include photovoltaic and thermal engineering in any combination in a solar cell or material. Said use may further include thermal, plasmonic or photovoltaic solar cells or materials in any combination. Plasmonics is the study of the interaction between light and matter. The use of light-matter interactions may be used to control localized thermal conditions down to or below the length scale of a single nanometer and down to or below the timescale of a single picosecond. Strong light-matter interactions are found in metallic nanostructures. Metal nanostructures or nanopatterned metallic or nonmetallic structures have been shown to absorb light more precisely and efficiently than other materials.

The invention described herein may be used to exploit solar or light energy more efficiently. The loss mechanism in typical solar cell conversion efficiency is between 95% and 99%. Commercially available silicon based semiconductor dielectric materials have a power conversion efficiency rate of approximately 10%. Because of their complex structure and precise engineering requirements, the wafers from which these photovoltaic solar cells are made are expensive to produce and consume significant energy in the fabrication process thereby offsetting any economic or environmental benefits. The failure rate in wafer fabrication is as high as 50%, which adds to the ecological disadvantages. Silicon materials are fragile in operation and deployment with limited lifetimes and diminishing performance. A new generation of photovoltaic solar cells has been proposed using organic polymer or plastic thin film combined with nanostructured inks or dyes. It has been claimed that these materials can be fabricated more easily and at a lower cost than silicon based devices. The demonstrated power conversion efficiency rate for this class of solar cells is only 1%. These materials, which are not yet widely available, may be more robust than silicon, but would need to be deployed over massive areas. No solar cells or materials have been developed or proposed that combine the use of photovoltaic and thermal engineering for more efficient conversion. All of the current and proposed photovoltaic and thermal solar cells/materials use toxic, inorganic or ecologically harmful materials and consume substantial fossil fuel or non-renewable energy supplies in fabrication and manufacture. The invention described herein may combine photovoltaic, plasmonic and thermal engineering with a variety of non-toxic, organic, recyclable and ecologically stable materials. Said invention may provide improved power conversion efficiency and power generation at lower fabrication or energy costs with reduced environmental impact.

In an exemplary embodiment the invention described herein could enable solar or light energy to fabricate or supply power for the fabrication of materials or devices. Said fabrication could be accomplished by any method or mean including those identified herein. Said materials or devices could be used for the production of solar, photovoltaic, plasmonic, thermal or other energy in any fashion or in the manner described in this invention. Solar or light energy may be used in the manner described in this invention to manufacture and produce materials or devices in an energy efficient manner.

The development of optical cavities for laser applications is well known. Photons trapped in an optical cavity repeatedly interact with emitters located inside the cavity. If the optical quality factor of the cavity is high photons are trapped for longer periods of time and the interaction between light and matter is enhanced. The repeated interaction of the photons and emitter in the cavity can result in feedback to enhance or suppress emissions. Metallic nanostructures or nanopatterned metallic or nonmetallic structures offer a unique opportunity to substantially increase the rate of emissions through surface plasmon excitations, i.e. collective electron oscillations. It has been established that metallic antenna or receiver nanostructures or nanopatterned metallic or nonmetallic structures enable strong field concentration by means of phase matching freely propagating light waves to local antenna modes. An important aspect of the invention described herein concerns the means to capture and concentrate the maximum light energy by the most efficient combination of nanostructured or nanopatterned metallic, organic or metalorganic materials. A feature of the invention described herein may include incorporating said materials in an antenna, receiver, collector, waveguide or other focusing or concentrating device for or as part of a photovoltaic, plasmonic or thermal solar cell/material structure or design.

In a further embodiment, the invention described herein may be used for the generation of energy through the use of light-matter interactions driven by a laser, lamp, light or solar energy by use of some or all of the following steps:
1) Deploy metallic, organic or metal organic nanostructures, micro structures, nanopatterned structures or nanoengineered materials as antennas or receivers to acquire and direct light energy from solar or any other source into or on to any coating, material, structure or substrate.
1) Inscribe, write, print, etch, engrave, roughen, cavitate, fabricate, coat, pit or otherwise treat or impress the surface or subsurface of any material or substrate to produce regular or random patterns, designs, gratings or waveguides to separate the light energy into discrete wavelengths or frequencies.
1) Use transparent nanopatterned metallic structures or films as dielectric waveguide materials to separate the light energy into discrete wavelengths or frequencies.
1) Enhance and concentrate field intensity using metallic nanostructures or micro structures or nanopatterned structures by surface plasmon excitations.
1) Enhance localized field effects to stimulate photon emission rates.
1) Control and focus enhanced photon emissions through a combination of metallic or nonmetallic nanoparticles or nanoparticle materials absorption, morphology, size, distribution, geometry, positioning, composition or similar factors.
1) Combine transparent nanopatterned metallic or nonmetallic structures or thin-films as contacts or electrodes to create organic photovoltaic subcells or multijunction stacks.
1) Spectrally or optically tune the organic photovoltaic subcells or multijunction stacks.
1) Enhance absorption properties through the conductivity of transparent metal contacts.
1) Use metallic or nonmetallic nanoparticles, micro structures, or nanopatterned structures to act as strong absorbers of light energy with a high thermal index realization.
1) Use selective absorption of ultraviolet light to act as a coating or filter in any organic material.
1) Select or combine metallic or nonmetallic nanoparticles, micro structures, or nanopatterned structures which have a plasmon resonance that matches the frequency of ultraviolet light to act as an absorption coating or filter in any organic material.
1) Use the absorption properties of selected metallic or nonmetallic nanoparticles, micro structures, or nanopatterned structures to efficiently absorb ultraviolet light from solar or other sources and prevent degradation of organic materials.
1) Convert the ultraviolet light absorbed from solar or other light sources to heat by means of said absorption. Use, transport or store the heat so acquired for any purpose.
1) Acquire light energy across any portion of or the entire spectrum.
1) Convert acquired light energy into heat.
1) Use the plasmon resonant frequency of metallic or nonmetallic nanostructured materials to separate the acquired light energy spectrum into discrete wavelengths.
1) Use the plasmon resonant frequency for excitation of surface plasmons to enhance transmission of light energy to a desired area.
1) Use metallic or nonmetallic nanoparticles, micro structures, or nanopatterned structures for plasmon enhanced catalysis to convert light energy into heat or to start catalytic or chemical reactions.
1) Transfer generated heat to a gas, liquid, solid, plasma or any other material.
1) Combine gas, liquid, solid, plasma or any other material with or in proximity to heated nanoparticle surfaces, micro structures, or nanopatterned structures.
1) Transfer heat to a reactor or chamber to drive a turbine, engine, stirling engine, alternator, converter, photovoltaic converter, generator, dynamo or any other device for the creation of electrical current or for any purpose.
1) Use heat derived from light energy to excite the molecular or kinetic properties of a gas, liquid, solid, plasma or any other material for any purpose or to drive a turbine, engine, stirling engine, alternator, converter, photovoltaic converter, generator, dynamo or any other device for the creation of electrical current or for any purpose.
1) Combine or incorporate any or all of the aforementioned materials into a coating, compound, composite, thin film, cell or any other form factor.
2) Incorporate or integrate any or all of the coating, compound, composite, thin film, cell or any other form factor materials containing any or all of the features described herein as an internal or external aspect or means to use light energy or heat to drive a turbine, engine, stirling engine, alternator, converter, photovoltaic converter, generator, dynamo or any other device or for any purpose.

This embodiment may use any or all of the aforementioned steps in combination with each other or alone. The steps may be used in this order or in any other order with omission or addition of any other steps.

In an exemplary embodiment, some of the steps listed in the previous embodiment may be used for or in conjunction with some or all of the following methods or steps:
1) Engineering a tunable, addressable black body structure to control convection, conduction, concentration, absorption, radiation, emission, and scattering of radiation.
2) Said structure could be applied to any substrate.
3) Such structure may have the ability to enhance the thermal, electrical or photovoltaic properties of any substrate.
4) The substrate or part of the substrate may act as a heat sink.
5) Solar radiation absorbed by said structure may be transferred to the substrate or to a separate heat sink.
6) Heat may be transferred to a working fluid, gas, plasma or liquid and used to drive a turbine, generator, alternator, converter, photovoltaic converter or similar device to create electrical energy or for any other purpose.
7) Engineering an evacuated transparent or opaque structure.
8) Provision of a space or spaces in said structure filled by a vacuum or gas.
9) Placement or positioning on the interior or exterior of said structure of materials designed to act as filters, intermediate absorbers and selective emitters or for any other purpose.

In an exemplary embodiment, some of the steps listed in the previous embodiments could be used for a thermal solar application. Metallic or nonmetallic nanostructures, micro structures, or nanopatterned structures could be incorporated into thermal solar cells or materials to collect, separate or absorb light and act as waveguides. The acquired light energy can be converted into heat by absorption, reflection or otherwise. The heat can be transferred to a gas, liquid, solid or plasma and used for any purpose. The heat can be used with or in a reactor or chamber to drive a turbine, engine, stirling engine, alternator, converter, photovoltaic converter, generator, dynamo or any other device for the creation of electrical current or for any purpose. Alternatively, the light energy or heat can be used to excite the molecular or kinetic properties of a gas or liquid to drive a turbine, engine, stirling engine, alternator, converter, photovoltaic converter, generator, dynamo or any other device for the creation of electrical current or for any purpose.

In an alternative exemplary embodiment, some of the steps listed in the previous embodiments could be used in conjunction with existing photovoltaic solar cells to create thermal photovoltaic solar cells. To enhance the existing photovoltaic solar cells, metallic or nonmetallic nanostructures, micro structures, or nanopatterned structures can be used as antennas or receivers to capture light energy from solar or other sources. The light can be separated into discrete wavelengths using transparent nanopatterned metallic structures or films. The localized field effects can be enhanced to stimulate photon emission rates. These photon emissions can be controlled and focused through metallic or nonmetallic nanoparticle, micro structures, or nanopatterned structures absorption, morphology, size, distribution, geometry, positioning, composition or similar factors. The transparent nanopatterned metallic structures or thin-films can be combined as contacts or electrodes to create organic photovoltaic subcells or multijunction stacks. These subcells or multijunction stacks can be spectrally or optically tuned. Absorption properties may be enhanced through the conductivity of transparent metal contacts.

In a further embodiment some of the steps listed in the previous embodiments could be used to combine thermal solar materials with photovoltaic solar cells. In an example of such an application metallic or nonmetallic nanostructures, micro structures, or nanopatterned structures can also be used to convert light energy into heat by absorption or reflection. The heat can then be transferred to a gas, liquid or plasma. The heat can be used for any purpose or to drive a turbine, engine, stirling engine, alternator, converter, photovoltaic converter, generator, dynamo or any other device for the creation of electrical current. The heat can also be used to excite the molecular or kinetic properties of a gas, liquid, solid, plasma or any other material for any purpose or to drive a turbine, engine, stirling engine, alternator, converter, photovoltaic converter, generator, dynamo or any other device for the creation of electrical current.

In an alternative embodiment, some of the steps listed in the previous embodiments could be used for the creation of thermal plasmonic solar cells or materials. Metallic or nonmetallic nanostructures, micro structures, or nanopatterned structures can be used to collect light. The plasmon resonant frequency of metallic or nonmetallic nanostructured or nanopatterned materials can be used to separate the acquired light energy spectrum into discrete wavelengths. The plasmon frequency can be used for excitation of surface plasmons to enhance transmission of light energy to a desired area. The metallic or nonmetallic nanoparticles, micro structures, or nanopatterned structures can be used for plasmon enhanced catalysis to convert light energy into heat or to start catalytic or chemical reactions. The metallic nanostructures can also be used to generate heat through absorption or reflection without using the plasmon resonance effect. Heat generated through absorption or reflection and heat generated through plasmon enhanced catalysis can be transferred to a gas, liquid, solid or plasma. The gas, liquid, solid or plasma can be combined with or placed in proximity to heated nanoparticle surfaces to generate heat for any purpose. Heat can be used in or transferred to a reactor or chamber for any purpose or to drive a turbine, engine, stirling engine, alternator, converter, photovoltaic converter, generator, dynamo or any other device for the creation of electrical current. The heat derived from light energy can be used to excite the molecular or kinetic properties of a gas or liquid for any purpose or to drive a turbine, engine, stirling engine, alternator, converter, photovoltaic converter, generator, dynamo or any other device for the creation of electrical current.

In a further exemplary embodiment, some of the steps in the previous embodiments can be used to create a plasmonic photovoltaic solar cell or material. For the photovoltaic application, metallic or nonmetallic nanostructures, micro structures, or nanopatterned structures can be used as antennas or receivers to capture light energy from solar or other sources. The light can be separated into discrete wavelengths using transparent nanopatterned metallic structures or films. The localized field effects can be enhanced to stimulate photon emission rates. These photon emissions can be controlled and focused through metallic or nonmetallic nanoparticle, micro structures, or nanopatterned structures, absorption, morphology, distribution, geometry, size, positioning, composition or similar factors. The transparent nanopatterned metallic structures or thin-films can be combined as contacts or electrodes to create organic photovoltaic subcells or multijunction stacks. These subcells or multifunction stacks can be spectrally or optically tuned. Absorption properties may be enhanced through the conductivity of transparent metal contacts.

In an alternative embodiment of the invention described herein the efficiency of plasmonic composite solar cells/materials may be improved by means of increasing the photon/electron emissions. The standard emission ratio in a photovoltaic solar cell device is one electron per one photon. By manipulating the size, shape or geometry of the nanomaterials or nanostructures through which light passes an increase in emissions may be achieved. Particles at a size of or below 100 nm contain a larger number of high energy surface electrons clustered in close proximity to one another. Since such high energy surface electrons are already in motion they can be more easily stimulated by the arriving photons. This may allow for a change in the ratio of photon electron emissions to permit up to seven surface electrons to be dislodged for each arriving photon. Stimulation of electron emissions would increase the generation of electrical power in a significant manner.

It is well known that optical fibers made of glass, plastic, polymer or other materials can be used to transmit light. Fiber optic materials enable light to be transmitted with minimal degradation over very significant distances, i.e. hundreds or thousands of kilometers. Light may also be transmitted in a free space medium such as air. This technology known as free space optics may use targeted guided light or laser beams without containment. The same technology may be deployed in microstructured optical fibers or in any other form or fashion including the use of a hollow or a partially hollow contained medium filled with air, gas or a vacuum.

In a further embodiment, the invention described herein may include the transfer of light collected in a specific location to one or many other or distant locations. By use of some or all of the following steps:
1) A device may capture light in a specific location or locations and transmit the light via fiber or free space optics or by any other means to one or many alternative locations
2) The transmitted light may then be used at any of such secondary locations with a plasmonic reactor device or in any other fashion to complete any or all of the steps of the previous embodiments.
3) Electricity may be generated at such locations by photovoltaic or any other means.
4) Light may be used at such locations to generate heat by any means including plasmon enhanced catalysis or chemical reactions.
5) Heat so generated at any location can be used for any purpose or to drive a turbine, engine, generator or other device for electrical current generation.

This embodiment demonstrates the unique ability to use solar or light energy in a distant, dark or subterranean environment to generate heat and electricity. This embodiment may use any or all of the aforementioned steps or any of the steps identified in any other embodiment in combination with each other or alone. The steps may be used in this order or in any other order with omission or addition of any other steps.

In an exemplary embodiment, the invention described herein could use any methods or materials to collect light by use of some or all of the following steps:
1) Said methods may include any light sensitive materials, glass, optical fiber, glass fiber or any light transmitting material in any form
2) Optical fibers may be used as the most efficient materials to collect and focus light
3) Open-ended or open-faced optical fibers or any other material embedded in or coated with a transparent thin film material could be used to capture and focus light
4) Fibers or any other material could be arranged in convex, concave, or any other formation or design to maximize light absorption
5) Software for multidimensional computer assisted simulations and modeling may be used to design such materials and formations to maximize capture of the most incident or critical angles of light

6) Such software could also be used to design the optimum forms, shapes, surfaces, structures and materials to maximize exposure to and collection of light
7) Software simulation and modeling may be used to analyze light scattering, reflection, diffraction, radiation, emission, convection, conduction, concentration and absorption properties and to maximize all of those elements in the design of materials, surfaces and structures
8) Bundles, clusters or other arrangements of optical fibers, single fibers or any other materials could be tuned to the entire spectrum of light

This embodiment may use any or all of the aforementioned steps in combination with each other or alone. This embodiment may use any or all of the aforementioned steps or any of the steps identified in any other embodiment in combination with each other or alone. The steps may be used in this order or in any other order with omission or addition of any other steps.

In an exemplary embodiment this invention may include exciting electromagnetic energy in a structure or material, which contains an addressable plasmon resonant frequency so as to influence one or more specific properties of said structure or material. In some implementations this provides a means to use electromagnetic excitation or light-matter interactions to influence, cause, control, modulate, stimulate or change the state or phase of electrical, magnetic, optical, thermal, acoustic or electromagnetic charge, emission, conduction, recording, information, data management, storage or similar properties. The method could include the use of light-matter interactions to generate electromagnetic excitation and concentrate extremely localized field effects or concentrated plasmonic field effects to cause an exchange of energy states in a material or structure. Said field effects could be used for excitation of surface electrons in metallic nanostructures causing said electrons to exchange energy states or said field effects could be used to mediate or stimulate photon emissions or modulate photonic energy to excite or stimulate emissions of electrons.

The method of use disclosed could provide a means to realize local thermal conditions at the nanoscale below the diffraction limit for the electromagnetic waves used. In some implementations surface plasmon excitations may be used to achieve desired thermal conditions at the nanoscale. Nanoscale objects or apertures at the nanoscale allow electromagnetic energy to be addressed, concentrated or restricted to critical dimensions that are below the diffraction limit of the wavelength of irradiation used. These concentrated fields can be used by means of absorption to efficiently heat volumes of material down to or below the scale of a single nanometer. Due to the small heat capacity that volume of material would cool rapidly when the electromagnetic excitation or light-matter interactions is terminated. Depending on the thermal environment of the heated volume cooling could take place on a timescale down to or below a single picosecond. The concentration could lead to massive field enhancements which may enable more precise control of light-matter interactions and local heating.

In the chemical industry metal nanostructures play a vital role as catalysts and are used in bulk quantities. It is well known that solid catalysts and systems employing solid catalysts can limit or restrict the speed and efficiency of chemical reactions. These issues require more precise control of catalyst heating and more precise placement of catalysts and chemicals. The invention described herein concerns the ability to address instantaneous delivery of localized focused heating to a desirable catalyst in a structure permitting precise placement to the desired chemical, reactant or product. Plasmon enhanced chemical reactions provide the means to determine and to change the exact location where a solid or structured catalyst is heated and by such heating to determine when and where reactions take place. The ability to focus heating in a specific area and rapidly change the delivery of that focused heating to adjacent areas permits the creation of high temperature regions surrounded by regions at lower temperatures. The large temperature gradient will result in rapid heat transport from the reaction site.

In an exemplary embodiment the invention described herein may be used for the initiation and control of catalysis, chemical reactions, photocatalysis, photochemical, photosynthesis, photovoltaic, electrocatalysis, catalytic chemical reactions and chemical synthesis including Fischer-Tropsch (FT), Haber-Bosch (HB) and other exothermic or endothermic reactions. The method may incorporate metallic, nonmetallic, metalorganic, inorganic, nanoparticle catalysts or nanostructures containing said catalysts to be included in any structure or device. The use of light-matter interactions or electromagnetic excitation including solar energy or laser light to control and direct localized thermal conditions down to or below the length scale of a single nanometer and down to or below the timescale of a single picosecond in said catalysts or devices may allow for more precise chemical reactions to be initiated and controlled in those reactors, structures or devices. Rapid changes in the delivery and location of focused heating will reduce cycling times for repeated heating and cooling to improve the efficiency and yield of chemical reactions and processing. The following are examples of types of catalytic chemical reactions that could be initiated and controlled in this manner or otherwise by means of the invention described herein, e.g. synthesis of hydrocarbons from CO and H₂, steam reforming, acetylation, addition reactions, alkylation, dealkylation, hydrodealkylation, reductive alkylation, amination, aromatization, arylation, carbonylation, decarbonylation, reductive carbonylation, carboxylation, reductive carboxylation, reductive coupling, condensation, cracking, hydrocracking, cyclization, cyclooligomerization, dehalogenation, dimerization, epoxidation, esterification, exchange, halogenation, hydrohalogenation, homologation, hydration, dehydration, hydrogenation, dehydrogenation, hydrocarboxylation, hydroformylation, hydrogenolysis, hydrometallation, hydrosilation, hydrolysis, hydrotreating, hydrodesulferization/hydrodenitrogenation (HDS/HDN), isomerization, methanol synthesis, methylation, demethylation, metathesis, nitration, partial oxidation, polymerization, reduction, steam and carbon dioxide reforming, sulfonation, telomerization, transesterification, trimerization, water gas shift (WGS), and reverse water gas shift (RWGS).

The various features, process, methods, means or structures of the invention described herein could be expressed in any combination in any or all of the following or any other architectures, form factors, materials or combination of materials including:

A metallic

A nonmetallic

An organic

An inorganic

A metal organic

A metal organic compound

An organometallic

A metal oxide

An oxide

A metal oxide film

A metal oxide composite film

A silicon

A silica

A silicate

A ceramic

A composite

A compound

A polymer

An organic composite thin film

An organic composite coating

An inorganic composite thin film

An inorganic composite coating

An organic and inorganic composite thin film

An organic and inorganic composite coating

A thin film crystal lattice nanostructure

An active photonic matrix

A flexible multi-dimensional film, screen or membrane

A microprocessor

A MEMS or NEMS device

A microfluidic or nanofluidic chip

A single nanowire, nanotube or nanofiber

A bundle of nanowires, nanotubes or nanofibers

A cluster, array or lattice of nanowires, nanotubes or nanofibers

A single optical fiber

A bundle of optical fibers

A cluster, array or lattice of optical fibers

A cluster, array or lattice of nanoparticles

Designed or shaped single nanoparticles at varying length scales

Nanomolecular structures

Nanowires, dots, rods, particles, tubes, sphere, films or like materials in any combination

Nanoparticles suspended in various liquids or solutions

Nanoparticles in powder form

Nanoparticles in the form of pellets, liquid, gas, plasma or otherwise

Nanostructures, nanoreactors, microstructures, microreactors, macrostructures or other devices

Combinations of nanoparticles or nanostructures in any of the forms described or any other form

Nanopatterned materials

Nanopatterned nanomaterials

Nanopatterned micro materials

Micropatterned metallic materials

Microstructured metallic materials

Metallic micro cavity structures

Metal dielectric material

Metal dielectric metal materials

Autonomous self-assembled or self-assembling structure of any kind

Combination of dielectric metal materials or metal dielectric metal materials

A semiconductor

Semiconductor materials including CMOS, SOI, germanium, quartz, glass, inductive, conductive or insulation materials, integrated circuits, wafers, or microchips

An insulator

A conductor

A paint, coating, powder or film in any form containing any of the materials identified herein or any other materials in any combination

All or any of the materials or forms described herein may be designed, used or deployed on or in flexible, elastic, conformable structures. Said structures or surface areas may be expanded or enlarged by the use of advanced non-planar, non-linear geometric and spatial configurations.

Nanowires are typically grown in random arrays using a variety of chemical vapor deposition (CVD) techniques. The successful introduction of nanowires into electronic circuitry will require synthesis of nanowires in well-defined locations with controlled composition, diameter, and growth orientation. CVD is a key process for the fabrication of semiconductors, microelectronics, photonics and nanomaterials. There are a number of CVD methods in current use, e.g. Laser Assisted CVD (LACVD), Low Pressure CVD (LPCVD), Metal-Organic CVD (MOCVD), Plasma Enhanced CVD (PECVD) and Thermal Activation CVD (TACVD). In unique contrast to all existing methods of CVD the invention described herein includes a means to generate a thermal environment that can be controlled through the interaction of electromagnetic excitations with designed objects or apertures at length scales down to or below a single nanometer and timescales down to or below a single picosecond.

In an exemplary embodiment this invention may include initiation and control of electromagnetic energy in a structure or material, which contains an addressable plasmon resonant frequency, so as to influence one or more specific properties of said structure or material. It may also include combining conventional nanoparticle catalyzed CVD nanowire growth with surface plasmon induced local heating of the catalyst particle. Local heating of selected nanoscale regions can enable growth of nanowires in well-defined locations on a chip and thereby solve a number of issues associated with conventional CVD. Existing CVD methods for growing nanowires at positions defined by the precise placement of catalyst particles require relatively high temperatures. This makes conventional CVD unsuitable for positioning on many materials including plastics, glass and certain silicon surfaces used in standard semiconductor chip synthesis. Initiation and control of nanothermal plasmonic engineering for CVD could overcome this limitation and enable the creation of entirely new classes of devices, materials, and combinations of materials.

The technology described herein may support low power, low cost, solar or other forms of photosynthesis or photocatalysis for controlled localized production of methane and hydrogen. In the near term existing hydrocarbon materials could be used. Ultimately decomposition or conversion of organic materials could serve as a clean renewable energy resource. This offers the potential for a prolonged and broadly based development of alternative hydrocarbon and fossil fuels.

In a further exemplary embodiment, the invention described herein could be used to transfer heat generated in a specific location to one or many other locations. Heat may be generated by some or any of the steps listed in the previous embodiments. Heat may be transferred without significant loss using materials with a low conductive index such as a plastic or polymer. Heat may also be transferred by metal encased in a low conductive index material. Heat can be transferred to a gas, liquid, solid, plasma or any other material and used for any purpose including to excite the molecular or kinetic properties of a gas or liquid for any purpose or to drive a turbine, engine, stirling engine, generator, converter, photovoltaic converter, alternator, dynamo or any other device for the creation of electrical current.

In an alternative exemplary embodiment, some or all of the features contained in the invention described herein may be used in the construction and operation of a turbine, engine, stirling engine, generator, photovoltaic converter, alternator, dynamo or any other device for the creation of electrical current or for any purpose by using some or all of the following steps:
1) A structure made of any material and in any shape, including a sphere, cylinder, or tube may contain or support a magnetic or conductive energy field
2) Movement of conductive materials or a magnetic field in proximity to one another may be converted into an electrical current by driving, rotating, spinning or moving the material or field
3) Heat may be converted into an electrical current by the use of thermoelectric nanostructures, structures materials or devices
4) The interior of said structure or material may be coated with metallic or nonmetallic nanoparticles, micro structures, or nanopatterned structures.
5) Said structure or material may be filled with a gas or liquid
6) A moving object may be introduced into said structure or material
7) Said moving object may incorporate metal or conductive windings, coils or other structures
8) Solar, laser or other light energy sources may be used to heat the metallic or nonmetallic nanoparticles, micro structures, or nanopatterned structures.
9) Said heat may cause said thermoelectric materials to generate an electrical current sufficient to activate a magnetic field
10) Said magnetic field may cause said moving object to be suspended within an enclosed raceway, groove, track or similar structure
11) Said heat may cause the gas or liquid to expand
12) Said expansion may cause the movement of said object within said structure
13) Said movement may cause the generation of an electrical current

This embodiment may use any or all of the aforementioned steps in combination with each other or alone. This embodiment may use any or all of the aforementioned steps or any of the steps identified in any other embodiment in combination with each other or alone. The steps may be used in this order or in any other order with omission or addition of any other steps.

An electrical current generated from or by a plasmonic reactor device/composite solar cell or material may be conducted by a conduit. Whenever an alternating current is generated, it may be conducted to or for use at an electrical utility, electrical provider, an electrical grid or for any purpose or converted to a dielectric current and stored or used for any purpose. Whenever a dielectric current is generated, it may be stored, or converted to an alternating current and conducted to or for use at an electrical utility, electrical provider, an electrical grid or for any purpose.

In any embodiment or description contained herein the method of enabling the various functions, tasks or features contained in this invention includes performing the operation of some or all of the steps outlined in conjunction with the preferred processes or devices. This description of the operation and steps performed is not intended to be exhaustive or complete or to exclude the performance or operation of any additional steps or the performance or operation of any such steps or the steps in any different sequence or order.

The foregoing means and methods are described as exemplary embodiments of the invention. Those examples are intended to demonstrate that any of the aforementioned steps, processes or devices may be used alone or in conjunction with any other in the sequence described or in any other sequence.

The following are some examples of industries or applications in which the invention described herein might enable significant scaling improvements, energy savings, cost efficiencies or disruptive technologies:

Energy and Transportation

Semiconductors

Photonics

Electronics

Fuel Cells

Waste Treatment

Desalinization

Catalysis

Pharmaceuticals

Diamond Material Production

Composite Materials

Photolithography

Photovoltaics (solar cells)

Photocatalysis

Fertilizer & Food Production

Chemicals

Coal Gasification and Liquefaction

Methane and Hydrogen Production

Biotech

Carbon Reclamation

Cosmetics

Medical

Memory & Storage

Coating & Finishing

Plastics & Polymers

Gas to Liquid Conversion

Direct Methane Conversion

Microfluidics

Gas Synthesis

Water Treatment

Food Production

Light Emitting Diodes

Thermal Energy Conversion

Power Generation

It will be apparent to any of those persons who are knowledgeable and skilled in the art that the aforementioned descriptions are merely examples of possible methods of enabling the inventions described. These descriptions are not intended in any way to limit or exclude alternative embodiments or uses of the inventions. All and any forms or embodiments or uses of the inventions are considered to be addressed and taught by the methods and descriptions illustrated and contained herein.

It is understood that the terms and descriptions used in connection with the devices, examples or implementations described herein are for illustrative purposes only and any variation, modifications or changes therein are intended to be included within the spirit and purview of this application and scope of the appended claims and combinations thereof.

It is also understood that the examples and implementations described herein are for illustrative purposes only and that various modifications or changes in light thereof will be suggested to persons skilled in the art and are to be included within the spirit and purview of this application and scope of the appended claims and combinations thereof.

What is claimed is:

1. A method of combining at least thermal engineering, plasmonics, photonics, electronics, photovoltaics, optical transfer, heat transport, light transport, catalysis or chemical reactions individually or in any combination for the enhancement or generation of solar, plasmonic, photovoltaic, thermal, optical, electrical or any other form of energy:
where at least metallic, organic, inorganic or metal organic nanostructures, micro structures, nanopatterned structures or nanoengineered materials are at least deployed as antennas or receivers to acquire and direct light energy from solar or any other source into or on to any coating, material, structure or substrate.
where at least light energy across any portion of or the entire solar spectrum is at least captured,
where at least transparent nanopatterned metallic or nonmetallic structures or films are used to at least focus, absorb, separate or otherwise manipulate light energy,
where at least transparent nanopatterned metallic or nonmetallic structures or films are used as at least a dielectric waveguide,
where at least any surface, subsurface, coating or film of any material or substrate is inscribed, written, printed, etched, engraved, roughened, cavitated, fabricated, coated, pitted or otherwise treated to impress the surface or subsurface of any material or substrate to produce regular or random patterns, designs, gratings or waveguides to separate the light energy into discrete wavelengths or frequencies.
where at least the size, shape, geometry, morphology, distribution, positioning, geometry, or composition of metallic or nonmetallic nanoparticles or nanoparticle materials, nanostructures, microstructures or nanopatterned structures are used,
where at least the size, shape, geometry, morphology, positioning, distribution or composition of metallic or nonmetallic nanoparticles or nanoparticle materials, nanostructures, microstructures or nanopatterned structures are used to at least stimulate, increase, control or focus absorption, photon emissions or exciton diffusion,
where at least any of at least photovoltaic, plasmonic or thermal engineering devices or materials are combined with any other,
where at least light energy can be used to at least fabricate or manufacture a solar cell, material or device,
where at least light energy is at least captured or concentrated by at least the combination of metallic or nonmetallic nanoparticles or nanoparticle materials, nanostructured or nanopatterned metallic, organic, inorganic or metalorganic materials,
where at least metallic, organic, inorganic or metal organic nanostructures, micro structures or nanopatterned structures or other materials are used as at least an antenna, receiver, collector, waveguide, focusing or concentrating device,
where at least metallic, organic, inorganic or metal organic nanostructures, micro structures or nanopatterned structures or other materials are used as at least part of a photovoltaic, plasmonic or thermal solar cell material structure or design,
where at least metallic or nonmetallic nanoparticles or nanoparticle structures, micro structures, or nanopatterned structures are used to convert light energy into heat or to start catalytic or chemical reactions,
where at least transparent nanopatterned metallic or nonmetallic structures, film or thin-film are used or combined as at least contacts or electrodes to create organic or inorganic photovoltaic subcells or multijunction stacks,
where at least organic or inorganic photovoltaic subcells or multijunction stacks are spectrally or optically tuned,
where at least absorption properties are enhanced through the conductivity of transparent metal contacts,
where at least selective absorption of ultraviolet light acts as a at least a coating, filter or absorber in any material,
where at least metallic or nonmetallic nanoparticles or nanoparticle materials, micro structures, or nanopatterned structures having a plasmon resonance that matches the frequency of ultraviolet light are at least used or combined to act as an absorber, absorption coating or filter in any material.

2. The method of claim 1 which combines or incorporates at least any or all materials into a coating, compound, composite, thin film or any other form factor for at least the following purposes:
where at least any or all of the coating, compound, composite, thin film, paint or any other form factor materials are incorporated, integrated or used to provide light energy or heat to drive at least a turbine, engine, stirling engine, alternator, converter, photovoltaic converter, generator, dynamo or any other device or for any purpose,
where at least a tunable, addressable black body structure is at least engineered to at least control any of convection, conduction, concentration, absorption, radiation, emission, and scattering of radiation,
where at least any or all of the said structure, compound, composite, thin film, paint or any other form factor materials could be applied to any substrate.
where at least any or all of the said structure, compound, composite, thin film, paint or any other form factor materials could enhance the thermal properties of any substrate,
where light energy from at least solar or any other light source is at least absorbed or reflected by any means and converted to heat to use for any purpose,
where thermal energy is at least created or used without affecting the temperature of adjacent materials,
where materials are used or deployed on or in at least flexible, elastic, conformable, configurable or reconfigurable structures,
where structures are used, designed, expanded or enlarged by at least planar, non-planar, linear, non-linear, geometric or spatial configurations.

3. The method of claim 1 where at least a means to seal, close or join a space, opening, cavity, region, junction or interface is used or deployed in at least any materials or structures using one or more of the following means:
where at least atmospheric pressure is used,
where at least air or any other gas is used,
where at least displacement of at least a gas, solid, liquid or plasma is used,
where at least a gel is used,
where at least a liquid, solid, or plasma is used,
where at least an aero gel is used,
where at least an electromagnetic or electrostatic charge is used,
where at least a vacuum is used,
where at least a gas or combination of gases is used,
where at least any material is combined or used with any other.

4. The method of claim 1 for design, construction or operation of a turbine, engine, stirling engine, generator, photovoltaic converter, alternator, dynamo or any other device for the creation of electrical current using one or more of the following means:
where at least a structure of any material or in any shape, including a sphere, cylinder, or tube can contain or support a magnetic or conductive energy field,
where at least the movement of conductive materials or a magnetic field in proximity to one another is converted into an electrical current by driving, rotating, spinning or moving the material or field,
where at least heat is converted into an electrical current by the use of thermoelectric or thermionic nanostructures or nanoparticle materials, structures materials or devices,
where at least the interior of a structure or material is coated with metallic or nonmetallic nanoparticles or nanoparticle materials, micro structures, or nanopatterned structures,
where at least a structure or material is filled with a gas or liquid,
where at least a moving object is introduced into a structure or material,
where at least a moving object incorporates metal or conductive windings, coils or other structures,
where at least solar, laser or other light energy sources are used to heat metallic or nonmetallic nanoparticles or nanoparticle materials, micro structures or nanopatterned structures,
where at least heat causes thermoelectric or thermionic materials to generate an electrical current,
where at least a magnetic field causes a moving object to be suspended within an enclosed raceway, groove, track or similar structure,
where at least heat can cause a gas or liquid to expand,
where at least expansion can cause the movement of an object within a structure,
where at least movement can cause the generation of an electrical current.

5. The method of claim 1 which contains at least any or all of the following or any other architectures, form factors, materials or combination of materials including metallic, nonmetallic, organic, inorganic, metal organic, organometallic, metal oxide, metal oxides, oxide, oxides, silicon, silica, silicate, ceramic, composite, compound, compound substances, polymer, plastic, organic composite thin film, organic composite coating, inorganic composite thin film, inorganic composite coating, organic and inorganic composite thin film, organic and inorganic composite coating, thin film crystal lattice nanostructure, active photonic matrix, flexible multi-dimensional film, screen or membrane, microprocessor, MEMS or NEMS device, semiconductors, insulator, conductor, semiconductor materials including CMOS, SOI, germanium, quartz, glass, inductive, conductive or insulation materials, integrated circuits, wafers, microchips, microfluidic or nanofluidic chips, single nanowire, nanotube or nanofiber, bundle of nanowires, nanotubes or nanofibers, cluster, array or lattice of nanowires, nanotubes or nanofibers, single optical fiber, bundle of optical fibers, cluster, array or lattice of optical fibers, cluster, array or lattice of nanoparticles, designed or shaped single nanoparticles at varying length scales, nanomolecular structures, nanowires, dots, rods, particles, tubes, spheres, films or like materials in any combination, nanoparticles suspended in various liquids or solutions, nanoparticles in powder form, nanoparticles in the form of pellets, liquid, gas, plasma or otherwise, nanostructures, nanoreactors, microstructures, microreactors, macrostructures or other devices, nanoparticles or nanostructures in any of the forms described or any other form, nanopatterned materials, nanopatterned nanomaterials, nanopatterned micro materials, micropatterned metallic materials, microstructured metallic materials, metallic micro cavity structures, metal dielectric materials, metal dielectric metal materials, an anode, a cathode, a self-assembled or self-assembling structure of any kind, a paint, coating, powder or film in any form containing any of the materials identified herein or any other materials.

6. A method of using at least a form of electromagnetic excitation or light-matter interactions in a structure or material having one or more addressable frequencies to generate the exchange of thermal, kinetic, electronic or photonic energy by or for one or more of the following:
where at least one material contains at least an addressable frequency in at least a gas, liquid, solid, plasma or any other material,
where at least electromagnetic excitation or light matter interactions are used to influence, cause, control, modulate, stimulate or change the state or phase of thermal, electrical, magnetic, optical, acoustic or electromagnetic charge, emission, conduction, recording, information, data management, storage or similar properties,
where at least light-matter interactions are used to generate electromagnetic excitation,
where at least light-matter interactions are used to at least concentrate electromagnetic energy to at least excite surface electrons,
where at least the excitation of one form of electromagnetic excitation or light-matter interaction is used to generate electromagnetic excitation and concentrate extremely localized field effects or concentrated plasmonic field effects,
where at least the excitation of one form of electromagnetic excitation or light-matter interaction is used to realize local thermal conditions at the nanoscale,
where at least surface plasmon excitations are used to achieve desired thermal conditions at the nanoscale,
where at least the excitation of one form of electromagnetic excitation or light-matter interactions is used for heating and cooling on a timescale down to or below a picosecond,
where at least light matter interactions or electromagnetic excitation are used to at least concentrate extremely localized field effects or concentrated plasmonic field effects to cause at least an exchange of energy states in a material or structure,
where at least plasmonic or other field effects are used for at least excitation of surface electrons in metallic nanostructures or any other structures causing said electrons to exchange energy states,
where at least plasmonic or other field effects are used to at least mediate or stimulate photon emissions or modulate photonic energy to excite or stimulate emissions of electrons,
where at least the size, shape or geometry of nanomaterials or nanostructures are used to stimulate or increase electron emissions,
where at least electron or photon emissions are used to drive at least photochemical, photocatalysis or photovoltaic reactions,
where at least an exchange of energy states is made to perform the function of at least a solar cell, capacitor, battery, transistor, resistor, semiconductor, information, data or signal storage, recording, acquisition, distribution, management, transport, retrieval, exchange, inversion or restoration.

7. The method of claim 2 where at least spatial or temporal control are obtained by at least restricting or directing electromagnetic excitation or light-matter interactions to specific objects or features embedded or located in or on at least a host matrix, material or substrate by any of the following means:
where at least localized thermal conditions are controlled by at least directing light-matter interactions at optical or other frequencies,
where at least electromagnetic excitation or light-matter interactions are used to at least generate localized thermal conditions to control or cause at least the combination, separation, reformation or reclamation of a gas, a combination of gasses, a material or a combination of materials in the form of a gas, plasma, solid or liquid,
where at least chemical reactions are employed for at least the generation, use, transfer or output of controlled localized thermal heat or energy,
where at least control of at least local thermal conditions down to or below the length scale of a single nanometer or down to or below the timescale of a single picosecond are achieved,
where at least one form of electromagnetic excitation or light matter interaction are initiated, controlled or terminated,
where at least electromagnetic excitation or light matter interactions for catalysis, synthesis, photocatalysis or photosynthesis are initiated, controlled, or terminated,
where at least electromagnetic excitation or light matter interactions to cause reactions or chemical reactions including endothermic or exothermic reactions are initiated, controlled, or terminated,
where at least localized heating at or below the length scale of a single nanometer caused by electromagnetic excitation is initiated, controlled or terminated,
where at least chemical vapor deposition or growth using light-matter interactions in metallic nanoparticles is initiated or controlled,
where at least said or any chemical or other reactions are initiated or controlled without heating the entire reaction chamber, the entire reactor mass, the entire reactant, the entire reaction product or the entire reactor substrate,
where at least rapid, controlled heating and cooling of at least a particle is achieved,
where at least rapid, controlled heating and cooling of at least a particle is used to enable micro and nano fabrication, patterning or molecular synthesis,
where at least rapid, controlled heating and cooling of at least a particle is used to cause chemical catalysis or chemical reactions,
where a light source heats at least a particle and is at least removed so that the particle cools and thermal energy is rapidly dissipated,
where at least rapid switching of thermal states of a particle is obtained,
where heat is used for any purpose including to drive at least a turbine, engine, stirling engine, generator, photovoltaic converter, alternator, dynamo or any other device to produce an electrical current,
where light matter interaction are at least used to initiate and control the generation, use, transfer and output of controlled localized thermal energy.

8. The method of claim 2 in which thermal engineering is used for any form of solar energy including in any combination at least a thermal, plasmonic or photovoltaic solar cell or material by any of the following means:
where localized field effects are enhanced to at least stimulate photon emission rates,
where enhanced photon emissions are at least controlled or focused through a combination of metallic or nonmetallic nanoparticle absorption, morphology, size, positioning, distribution, geometry, composition or similar factors,
where at least the absorption properties of at least selected metallic or nonmetallic nanoparticles or nanoparticle materials, micro structures, or nanopatterned structures are at least used to efficiently absorb ultraviolet light from solar or other sources and prevent degradation of materials,
where at least light energy absorbed from solar or any other light source is converted to heat by any means and used for any purpose,
where at least the plasmon resonant frequency of metallic or nonmetallic nanostructured materials is used to separate the acquired light energy spectrum into discrete wavelengths,
where at least the plasmon frequency for excitation of surface plasmons is at least used to enhance transmission of light energy to a desired area,
where at least heat is transferred to at least a gas, liquid, solid, plasma or any other material,
where at least the combination of gas, liquid, solid, plasma or any other material is in proximity to at least heated nanoparticle materials, surfaces, microstructures or nanopatterned structures for any purpose,
where at least heat is transferred to at least a reactor or chamber to drive at least a turbine, engine, stirling engine, alternator, photovoltaic converter, generator, dynamo or any other device for at least the creation of electrical current or for any purpose,
where at least heat derived from light energy is used to at least excite the molecular or kinetic properties of at least a gas, liquid, solid, plasma or any other material,
where at least the molecular or kinetic properties of at least a gas, liquid, solid, plasma or any other material are at least used to drive a turbine, engine, stirling engine, alternator, photovoltaic converter, generator, dynamo or any other device for the creation of at least electrical current or for any purpose.

9. The method of claim 2 where at least metallic or nonmetallic nanostructures, micro structures, nanopatterned, coatings, compounds, composites, thin films, paint or structures are incorporated into at least thermal solar cells or materials for any of the following means:
where at least said structures are used to at least collect, concentrate, separate or absorb light or at least act as waveguides,
where at least heat is transferred to at least a gas, liquid, solid or plasma,
where at least heat generated through plasmon enhanced catalysis is transferred to at least a gas, liquid, solid or plasma,
where at least heat is transferred using at least materials with a low conductive index,
where heat is transferred by at least a metal clad in a material with a low conductive index.

10. The method of claim 2 in which electrical current generated from or by at least a plasmonic reactor device/composite solar cell or material may be conducted by at least a conduit or any of the following means:
where at least an alternating current is generated, conducted to or used by at least an electrical utility, electrical provider, an electrical grid or for any purpose or at least converted to a dielectric current and stored or used for any purpose,
where a dielectric current is at least generated, stored or converted to an alternating current and conducted to or used by at least an electrical utility, electrical provider, an electrical grid or for any purpose,
where heat is converted into an electrical current by the use of at least thermoelectric or thermionic materials or means including at least nanoparticles or nanoparticle materials, nanostructures, microstructures, nanopatterned structures, structures, materials or devices,
where at least the interior of at least a structure or material is coated with at least metallic or nonmetallic nanoparticles or nanoparticle materials, nanostructures, microstructures or nanopatterned structures,
where at least the exterior of at least a structure or material is coated with at least metallic or nonmetallic nanoparticles or nanoparticle materials, nanostructures, microstructures or nanopatterned structures,
where at least a structure or material is filled with at least a gas, plasma or liquid,
where at least one material is an inverter,
where at least one material is a transmitter,
where at least one material is an inductor,
where at least one material is a conductor,
where at least one material is an insulator,
where at least one material is an anode,
where at least one material is a cathode.

11. A method of optical engineering to transfer light collected in at least one location to at least one or many other locations using any light sensitive materials including at least metal, organic, inorganic, metal organic, silicon, silica, silicate, ceramic, composite, polymers, plastics, paint, glass, quartz, silica, silicon, ceramic, optical fiber, glass fiber, air, gas or any other material using any of the following means:
where at least light is captured in a specific location and at least transmitted by at least a fiber, free space optics, air, gas or any other means to at least one or many locations,
where at least open-ended or open-faced optical fiber or any other material embedded in or coated with a transparent thin film material is used to capture and focus light,
where at least optical fiber or any other material is arranged in a convex, concave or any other formation or design to maximize light absorption,
where at least software for multidimensional computer assisted simulations and modeling is used to design materials and formations to maximize capture of the most incident or critical angles of light,
where at least software simulation and modeling is used to analyze light scattering, reflection, diffraction and absorption properties to at least maximize all of those elements in the design of materials, surfaces and structures,
where at least bundles, clusters or other arrangements of optical fibers, single fibers or any other materials are tuned to the entire spectrum of light,
where at least the transmitted light is used at least with a plasmonic reactor device or in any other fashion,
where at least light is used for the generation of electricity by thermal, thermionic, plasmonic, photovoltaic or any other means,
where at least light is used to at least generate heat by any means including at least plasmon enhanced catalysis or chemical reactions,
where at least heat is used for any purpose or to drive at least a turbine, engine, generator or any other device for electrical current generation,
where at least light sensitive materials, metal, organic, inorganic, metal organic, silicon, silica, silicate, ceramic, composite, polymer, plastics, polymers, paint, glass, quartz, silica, silicon, ceramic, optical fiber, glass fiber, air, gas or any other light transmitting material are used in any form,
where at least any material or structure is used to at least track, focus or concentrate light in at least a solar cell or material.
